(19) United States
(12) Patent Application Publication
(10) Pub. No.: US 2015/0091041 A1
(43) Pub. Date: Apr. 2, 2015

(54) SEMICONDUCTOR LIGHT EMITTING DEVICE AND SEMICONDUCTOR LIGHT EMITTING APPARATUS INCLUDING THE SAME

(71) Applicants: Ju Heon YOON, Hwaseong-si (KR); Myeong Ha KIM, Hwaseong-si (KR); Chan Mook LIM, Seongnam-si (KR); Joon Woo JEON, Seoul (KR); Jin Young CHOI, Seoul (KR)

(72) Inventors: Ju Heon YOON, Hwaseong-si (KR); Myeong Ha KIM, Hwaseong-si (KR); Chan Mook LIM, Seongnam-si (KR); Joon Woo JEON, Seoul (KR); Jin Young CHOI, Seoul (KR)

(21) Appl. No.: 14/454,559

(22) Filed: Aug. 7, 2014

(30) Foreign Application Priority Data
Sep. 27, 2013 (KR) 10-2013-0115674

(51) Int. Cl. H01L 27/15; H01L 33/38

(52) U.S. Cl. CPC H01L 27/15; H01L 33/38
USPC 257/99

(57) ABSTRACT

A semiconductor light emitting device includes a substrate, a first structure, a second structure, first and second n-electrodes, and first and second p-electrodes. The first structure is disposed on the substrate and includes a first n-type semiconductor layer, a first active layer, and a first p-type semiconductor layer. The second structure is spaced apart from the first structure on the substrate and includes a second n-type semiconductor layer, a second active layer and a second p-type semiconductor layer. The first n-electrode and the first p-electrode are connected to the first n-type semiconductor layer and the first p-type semiconductor layer, respectively. The second n-electrode and the second p-electrode are connected to the second n-type semiconductor layer and the second p-type semiconductor layer, respectively. The second n-electrode is spaced apart from the second active layer to encompass the second active layer.

### CROSS-REFERENCE TO RELATED APPLICATION

This application claims priority to, and benefit of Korean Patent Application No. 10-2013-0115674 filed on Sep. 27, 2013, with the Korean Intellectual Property Office, the entire contents of which are hereby incorporated by reference.

### TECHNICAL FIELD

The present disclosure relates to a semiconductor light emitting device and a semiconductor light emitting apparatus including the same.

### BACKGROUND

Light emitting diodes (LEDs), widely seen as next generation light sources, have many positive attributes such as relatively long lifespans, relatively low power consumption, rapid response rates, environmentally friendly characteristics, and the like, as compared to other light sources according to the related art, and have been used as important light sources in various products such as illumination devices, back light units for display devices, and the like. In particular, group III nitride-based LEDs including gallium nitride (GaN)-based LEDs, aluminum gallium nitride (AlGaN)-based LEDs, indium gallium nitride (InGaN)-based LEDs, indium aluminum gallium nitride (InAlGaN)-based LEDs, and the like have been used in semiconductor light emitting devices outputting blue or ultraviolet light. Recently, as LEDs have come into widespread use, the range of uses thereof is being broadened to encompass the field of high current, high output light sources. As such, as LEDs are required in the field of high current, high output light sources, research into improving light emitting characteristics in the field of LEDs has continued.

On the other hand, in order to protect light emitting devices from electrostatic discharge (ESD) at the time of operating light emitting devices using light emitting diodes, zener diodes are used, and in general, such zener diodes are mounted together with light emitting diodes in packages.

Accordingly, zener diodes having an improved ESD withstand voltage, while significantly reducing loss in light emission areas, have been demanded.

### SUMMARY

An aspect of the present disclosure relates to a semiconductor light emitting device having an improved withstand voltage against reverse ESD and a semiconductor light emitting apparatus including the same.

One aspect of the inventive concept encompasses a semiconductor light emitting device including a substrate; a first structure disposed on the substrate and including a first n-type semiconductor layer, a first active layer, and a first p-type semiconductor layer; a second structure disposed to be spaced apart from the first structure on the substrate and including a second n-type semiconductor layer, a second active layer and a second p-type semiconductor layer; and a first n-electrode and a first p-electrode connected to the first n-type semiconductor layer and the first p-type semiconductor layer, respectively; and a second n-electrode and a second p-electrode connected to the second n-type semiconductor layer and the second p-type semiconductor layer, respectively, wherein the second n-electrode is spaced apart from the second active layer so as to encompass the second active layer.

The semiconductor light emitting device may include a light emitting diode region in which the first structure is disposed and a zener diode region in which the second structure is disposed.

The second n-electrode may be spaced apart from the second active layer at a uniform interval so as to encompass the second active layer.

The second active layer may have a circular cross-sectional shape on a plane parallel to an upper surface of the substrate.

The second n-electrode may have a ring shape so as to encompass the second active layer.

The second n-electrode may have an open curved shape so as to encompass the second active layer.

The second structure may include a mesa region in a central portion thereof and an etched region including etched portion of the second n-type semiconductor layer, the second active layer and the second p-type semiconductor layer in the vicinity of the mesa region.

The mesa region may have a cylindrical shape.

The second p-electrode, not encompassing the second active layer, may be disposed on an upper surface of the mesa region, and may cover the entire upper surface of the second structure in the mesa region.

The second p-electrode, not encompassing the second active layer, may be disposed on an upper surface of the mesa region, and may cover a portion of the upper surface of the second structure in the mesa region.

The second p-electrode may be disposed on an upper surface of the mesa region, and the second n-electrode may be disposed on the second n-type semiconductor layer in an upper part of the etched region to encompass the second active layer.

The first n-electrode may be electrically connected to the second p-electrode, and the first p-electrode may be electrically connected to the second n-electrode.

The semiconductor light emitting device may further include a connection electrode connecting the first p-electrode to the second n-electrode.

The connection electrode may be spaced apart from the first and second structures by an insulating layer while extending along lateral surfaces of the first structure and the second structure.

The first p-electrode may include a pad portion and at least one finger portion extending from the pad portion, and the connection electrode may extend from the finger portion.

The first n-type semiconductor layer, the first active layer and the first p-type semiconductor layer, and the second n-type semiconductor layer, the second active layer and the second p-type semiconductor layer may each include the same material, and may have substantially the same maximum thickness.

The second structure may be located in a corner region of the substrate.

The first and second structures may further include a transparent electrode layer disposed on the first p-type semiconductor layer and the second p-type semiconductor layer, respectively.

Another aspect of the inventive concept relates to a semiconductor light emitting device including a substrate; alight emitting structure and a zener structure spaced apart from each other on the substrate and respectively including a plurality of first semiconductor layers and a plurality of second semiconductor layers; and a zener electrode unit including a first electrode and a second electrode on the zener structure, wherein the zener structure includes a mesa region including at least a portion of the plurality of first semiconductor layers, and the first electrode is spaced apart from the mesa region to encompass the mesa region.

The mesa region may have a cylindrical shape and the first electrode may have a ring shape to encompass the mesa region.

Still another aspect of the inventive concept encompasses a semiconductor light emitting apparatus including a package body having a first electrode structure and a second electrode structure; and the semiconductor light emitting device described above, located in the package body.

The first electrode structure may be electrically connected to the first n-electrode and the second p-electrode, and the second electrode structure may be electrically connected to the first p-electrode and the second n-electrode.

The first electrode structure may include conductive wires connected to the first n-electrode and the second p-electrode, and the second electrode structure may include a conductive wire connected to the first p-electrode.

The semiconductor light emitting device may include a first pad electrode electrically connected to the first n-electrode, a second pad electrode electrically connected to the second p-electrode, and a third pad electrode electrically connected to the first p-electrode and the second n-electrode, and the first to third pad electrodes may be disposed on one surface of the semiconductor light emitting device.

The semiconductor light emitting device may be mounted in the package body such that the first n-electrode, the first p-electrode, the second n-electrode and the second p-electrode may be directed upwardly thereof.

Still another aspect of the inventive concept relates to a semiconductor light emitting device including a substrate, a first structure, a second structure, first and second first-conductive-type electrodes, and first and second second-conductive-type electrodes. The first structure is disposed on the substrate and includes a first first-conductive-type semiconductor layer, a first active layer, and a first second-conductive-type semiconductor layer. The second structure is disposed to be spaced apart from the first structure on the substrate and includes a second first-conductive-type semiconductor layer, a second active layer and a second second-conductive-type semiconductor layer. The first first-conductive-type electrode and the first second-conductive-type electrode are connected to the first first-conductive-type semiconductor layer and the first second-conductive-type semiconductor layer, respectively. The second first-conductive-type electrode and a second second-conductive-type electrode are connected to the second first-conductive-type semiconductor layer and the second second-conductive-type semiconductor layer, respectively. The second first-conductive-type electrode is spaced apart from the second active layer so as to encompass the second active layer

### BRIEF DESCRIPTION OF DRAWINGS

The above and other aspects, features and other advantages will be more clearly understood from the following detailed description taken in conjunction with the accompanying drawings, in which like reference characters may refer to the same or similar parts throughout the different views. The drawings are not necessarily to scale, emphasis instead being placed upon illustrating the principles of the embodiments of the present inventive concept. In the drawings, the thickness of layers and regions may be exaggerated for clarity.

FIG. 1 is a schematic plan view of a semiconductor light emitting device according to an embodiment of the inventive concept.

FIGS. 2A and 2B are schematic cross-sectional views of a semiconductor light emitting device taken along line A-A′ and line B-B′ of FIG. 1, respectively.

FIG. 3 is an equivalent circuit diagram of a semiconductor light emitting device according to an embodiment of the inventive concept.

FIG. 4 is a schematic perspective view illustrating a zener diode region of a semiconductor light emitting device according to an embodiment of the inventive concept.

FIGS. 5A to 5C are schematic plan views illustrating zener diode regions of a semiconductor light emitting device according to an embodiment of the inventive concept.

FIGS. 6A to 10B schematically illustrate main processes of a method of manufacturing a semiconductor light emitting device according to an embodiment of the inventive concept.

FIGS. 11A and 11B are schematic plan views of a semiconductor light emitting device according to an embodiment of the inventive concept.

FIG. 12 is a schematic cross-sectional view of a semiconductor light emitting device taken along line A-A′ of FIG. 11A.

FIGS. 13 and 14 are respectively a perspective view and a cross-sectional view illustrating an example in which a semiconductor light emitting device is applied to a package according to an embodiment of the inventive concept.

FIGS. 15 and 16 are cross-sectional views illustrating examples in which a semiconductor light emitting device according to an embodiment of the inventive concept is applied to a backlight unit.

FIGS. 17 and 18 are exploded perspective views illustrating examples in which a semiconductor light emitting device according to an embodiment of the inventive concept is applied to an illumination device.

FIG. 19 illustrates an example in which a semiconductor light emitting device according to an embodiment of the inventive concept is applied to a vehicle headlight.

### DETAILED DESCRIPTION

Embodiments of the inventive concept will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

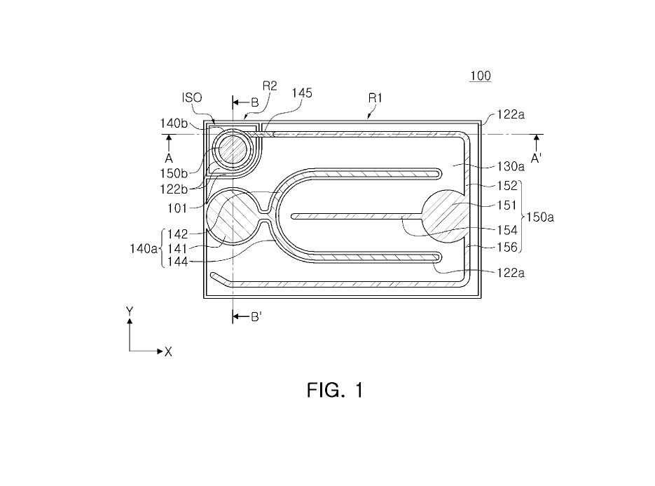

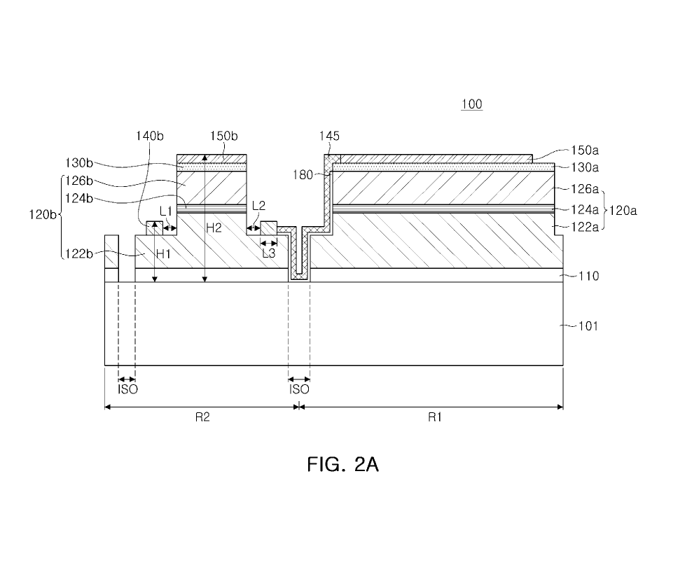

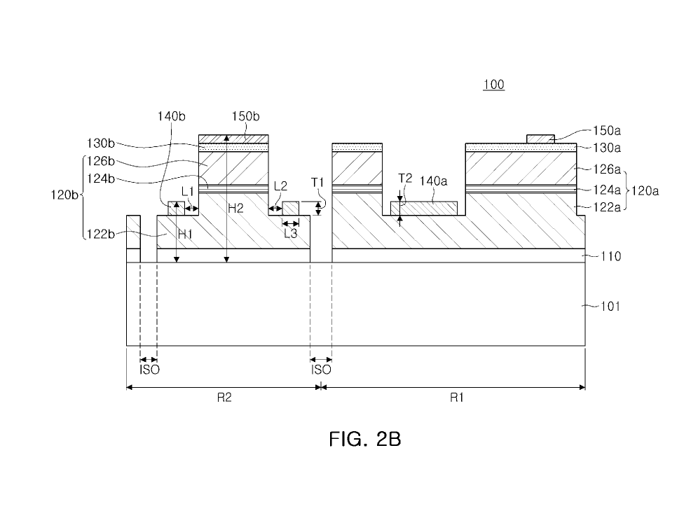

FIG. 1 is a schematic plan view of a semiconductor light emitting device according to an embodiment of the inventive concept. FIGS. 2A and 2B are schematic cross-sectional views of a semiconductor light emitting device taken along line A-A′ and line B-B′ of FIG. 1, respectively.

With reference to FIG. 1, a semiconductor light emitting device 100 may include a light emitting diode region R1, a zener diode region R2, and a device isolation region ISO formed therebetween. The semiconductor light emitting device 100 may have a monolithic structure in which the zener diode region R2 is integrated with the semiconductor light emitting device 100, such that the degree of integration of a device such as a package or a light emitting device may be improved and brightness thereof may be secured.

With reference to FIGS. 1 to 2B, the semiconductor light emitting device 100 may include a first structure 120a disposed in the light emitting diode region R1 and a second structure 120b disposed in the zener diode region R2. The first structure 120a may be electrically isolated from the second structure 120b through the device isolation region ISO.

The first and second structures 120a and 120b may include first and second n-type semiconductor layers 122a and 122b, first and second active layers 124a and 124b, and first and second p-type semiconductor layers 126a and 126b, respectively. In addition, the semiconductor light emitting device 100 may include a first n-electrode 140a and a first p-electrode 150a that are formed on the first structure 120a, and a second n-electrode 140b and a second p-electrode 150b that are formed on the second structure 120b, as an electrode structure. Transparent electrode layers 130a and 130b may be further formed on upper surfaces of the first and second p-type semiconductor layers 126a and 126b, respectively.

The terms ‘on’, ‘upper part’, ‘upper surface’, ‘below’, ‘lower part’, ‘lower surface’, ‘side surface’, and the like, as used in the inventive concept, are used based on the drawings, and may be changed depending on a direction in which a completed device is disposed.

A substrate 101 may have an upper surface extended in x and y directions (see FIG. 1). The substrate 101 may be a semiconductor growth substrate, and may be formed using an insulating, conductive semiconductor material such as sapphire, silicon carbide (SiC), MgAl₂O₄, MgO, LiAlO₂, LiGaO₂, GaN or the like. In the case of a sapphire substrate widely used as a nitride semiconductor growth substrate, sapphire is a crystal having Hexa-Rhombo R3c symmetry while having electric insulation, has respective lattice constants of 13.001 Å and 4.758 Å in c-axis and a-axis directions, and has a C (0001) plane, an A (11-20) plane, an R (1-102) plane and the like. In this case, since the C plane comparatively facilitates the growth of a nitride thin film and is stable at relatively high temperatures, the sapphire may be mainly used for a growth substrate for a nitride semiconductor. On the other hand, although not shown in the drawings, an upper surface of the substrate 101, for example, a growth surface for semiconductor layers, may include a plurality of concave-convex portions formed therein, and crystalline properties of the semiconductor layers, light emission efficiency thereof, and the like may be improved by such a concave-convex structure.

A buffer layer 110 may be formed to reduce the occurrence of lattice defects in the first and second structures 120a and 120b grown on the substrate 101, and may be formed of an undoped semiconductor layer formed of nitride or the like. For example, the buffer layer 110 may reduce a lattice constant difference between the substrate 101 formed of sapphire and the first and second n-type semiconductor layers 122a and 122b stacked on the substrate 101 and formed of GaN, such that crystalline properties of a GaN layer may be increased. The buffer layer 110 may include an undoped GaN layer, an undoped AlN layer, an undoped InGaN layer or the like, applied thereto, and may be grown to have a thickness of tens to hundreds of Å at a relatively low temperature of 500° C. to 600° C. Here, undoping may indicate a process in which a semiconductor layer is not separately subjected to an impurity doping process, but may also indicate an impurity concentration level originally contained in a semiconductor layer as it is, for example, when a nitride gallium semiconductor is grown using a metal organic chemical vapor deposition (MOCVD) method, Si or the like used as a dopant may be contained therein at a level of about 10¹⁴ to 10¹⁸/cm³.

The first and second structures 120a and 120b may configure a light emitting diode and a zener diode, respectively. The second structure 120b may be disposed in a portion of the substrate 101, and as shown in FIG. 1, may be located in a corner portion of the semiconductor light emitting device 100. For example, FIG. 1 shows the second n-type semiconductor layer 122b of the second structure 120b in an upper left corner of the semiconductor light emitting device 100. However, the second structure 120b may be variously disposed according to an embodiment of the inventive concept without being particularly limited. According to an embodiment of the inventive concept, in a region of the semiconductor light emitting device 100 not being adjacent to the first structure 120a, for example, on the left of the second structure 120b of FIG. 2A, the device isolation region ISO may be extended to an edge of the semiconductor light emitting device 100.

The second structure 120b may include a mesa region in a central portion thereof including a portion of the second n-type semiconductor layer 122b, the second active layer 124b and the second p-type semiconductor layer 126b, and an etched region including an etched portion of the second n-type semiconductor layer 122b, in the vicinity of the mesa region. The mesa region may have a cylindrical shape, and the second active layer 124b may have a circular cross-sectional shape on a plane parallel to an upper surface of the substrate 101, for example, on an x-y plane (see FIGS. 1 and 2). In the inventive concept, the term ‘circular’ may be used as a term indicating an arbitrary shape of closed lines, configured of curved lines without a vertex, as well as a curved line formed by dots having a predetermined distance from one point on a plane, and the term ‘cylindrical shape’ may also be used as a term indicating a column having a ‘circular’ cross-sectional shape. However, a cross-sectional shape of the second active layer 124b according to an embodiment of the inventive concept is not limited to being a circular shape, and according to a further embodiment of the inventive concept, the second active layer 124b may have a cross sectional shape which includes curved line and straight line regions.

The first and second structures 120a and 120b may include first and second n-type semiconductor layers 122a and 122b, first and second active layers 124a and 124b, and first and second p-type semiconductor layers 126a and 126b sequentially formed on the substrate 101, respectively. The first n-type semiconductor layer 122a, the first active layer 124a, and the first p-type semiconductor layer 126a of the first structure 120a may be formed of the same materials as materials of the second n-type semiconductor layer 122b, the second active layer 124b and the second p-type semiconductor layer 126b of the second structure 120b, respectively. In the mesa region and the etched region, the first n-type semiconductor layer 122a, the first active layer 124a, and the first p-type semiconductor layer 126a of the first structure 120a may have the same thicknesses as thicknesses of the second n-type semiconductor layer 122b, the second active layer 124b and the second p-type semiconductor layer 126b of the second structure 120b, respectively.

The first and second n-type semiconductor layers 122a and 122b may be configured of a semiconductor doped with an n-type impurity. The first and second p-type semiconductor layers 126a and 126b may be configured of a semiconductor doped with a p-type impurity. However, the present disclosure is not limited thereto and, conversely, the positions of the first and second n-type semiconductor layers 122a and 122b and the positions of the first and second p-type semiconductor layers 126a and 126b may be switched such that they are disposed in positions opposite to each other. In addition, the first and second n-type semiconductor layers 122a and 122b and the first and second p-type semiconductor layers 126a and 126b may be configured of a nitride semiconductor including a material having a composition of, for example, AlₓIn_{y}Ga_{1-x-y}N (0≦x≦1, 0≦y≦1, and 0≦x+y≦1). The first and second n-type semiconductor layers 122a and 122b and the first and second p-type semiconductor layers 126a and 126b may also be formed using, for example, a material of an AlGaInP-based semiconductor or an AlGaAs-based semiconductor.

The first and second active layers 124a and 124b may be p-n junction portions interposed between the first and second n-type semiconductor layers 122a and 122b and the first and second p-type semiconductor layers 126a and 126b, respectively, and may emit light having a predetermined amount of energy through the recombination of electrons and holes. The first and second active layers 124a and 124b may contain a material having an energy band gap smaller than that of the first and second n-type semiconductor layers 122a and 122b and the first and second p-type semiconductor layers 126a and 126b. For example, when the first and second n-type semiconductor layers 122a and 122b and the first and second p-type semiconductor layers 126a and 126b are GaN-based compound semiconductors, the first and second active layers 124a and 124b may include an InAlGaN-based compound semiconductor having an energy band gap smaller than that of GaN. In addition, the first and second active layers 124a and 124b may have a multiple quantum well (MQW) structure in which a quantum well layer and a quantum barrier layer are alternately stacked, for example, an InGaN/GaN structure.

The first and second n-electrodes 140a (see FIGS. 1 and 2B) and 140b may be electrically connected to the first and second n-type semiconductor layers 122a and 122b, respectively, and the first and second p-electrodes 150a and 150b may be electrically connected to the first and second p-type semiconductor layers 126a and 126b, respectively. The first and second n-electrodes 140a and 140b may be formed on an upper surface of the first and second n-type semiconductor layers 122a and 122b, respectively, in a single direction, based on the substrate 101. The first and second p-electrodes 150a and 150b may be formed on an upper surface of the first and second structures 120a and 120b, respectively, in a single direction, based on the substrate 101. However, the present disclosure is not limited thereto and, conversely, the positions of first and second n-electrodes 140a and 140b and the positions of the first and second p-electrodes 150a and 150b may be switched such that they are disposed in positions opposite to each other.

Referring to FIGS. 2A and 2B, in the first structure 120a, the first n-electrode 140a may be formed on the first n-type semiconductor layer 122a in a region in which the first structure 120a is mesa etched, the first p-electrode 150a may be formed on the first p-type semiconductor layer 126a, and the transparent electrode layer 130a may be interposed between the first p-electrode 150a and the first p-type semiconductor layer 126a. In addition, although not shown in the drawings, a separate current blocking layer formed of a transparent insulating material may be further formed in a region corresponding to the first p-electrode 150a below the first p-electrode 150a and the transparent electrode layer 130a, such that an electric signal applied from the first p-electrode 150a, for example, a current, may be easily dispersed uniformly in the first structure 120a through the transparent electrode layer 130a, without being limited to a lower part of the first p-electrode 150a.

Referring to FIG. 1, the first n-electrode 140a may include a pad portion 141 and a plurality of finger portions 142 and 144 extending in a single direction, for example, an x direction, from the pad portion 141 in a manner in which widths thereof are smaller than those of the pad portion 141, such that current is uniformly injected thereinto. In addition, the first p-electrode 150a may also include a pad portion 151 and a plurality of finger portions 152, 154, and 156. In order to increase light emission efficiency in the first structure 120a, the finger portions 142 and 144 of the first n-electrode 140a and the finger portions 152, 154 and 156 of the first p-electrode 150a may be disposed to alternate with each other. However, the shape and structure of the first n-electrode 140a and the first p-electrode 150a are provided by way of example, without being limited to those shown in the drawings.

In the second structure 120b, the second n-electrode 140b may be formed on the second n-type semiconductor layer 122b in the etched region in which the second structure 120b is mesa etched, and the second p-electrode 150b may be formed on the second p-type semiconductor layer 126b in the mesa region. In addition, the transparent electrode layer 130b may be interposed between the second p-electrode 150b and the second p-type semiconductor layer 126b.

The second n-electrode 140b may be spaced apart from the second active layer 124b by a predetermined distance so as to encompass the second active layer 124b. The second n-electrode 140b may be disposed to be spaced apart from the mesa region by a predetermined distance L1 or L2 so as to have a ring shaped cross section, and a width L3 thereof may be variously changed according to an embodiment of the inventive concept. An upper surface of the second n-electrode 140b may be positioned at a first height H1 from an upper surface of the substrate 101, and an upper surface of the second p-electrode 150b may be positioned at a second height H2, higher than the first height H1 from the upper surface of the substrate 101. However, according to an embodiment of the inventive concept, the second n-electrode 140b and the second p-electrode 150b may be disposed at the same level such that the first height H1 and the second height H2 are on the same level. In addition, referring to FIG. 2B, a first thickness T1 of the second n-electrode 140b may be equal or similar to that of a second thickness T2 of the first n-electrode 140a, but may be changed depending on a width of the second n-electrode 140b, a size of the second structure 120b, or the like, and for example, the first thickness T1 may be greater than the second thickness T2.

The transparent electrode layers 130a and 130b may be formed of a transparent conductive oxide layer having relatively excellent ohmic contact performance while having relatively high light transmissivity, and may be formed of at least one selected from indium tin oxide (ITO), zinc-doped indium tin oxide (ZITO), zinc indium oxide (ZIO), gallium indium oxide (GIO), zinc tin oxide (ZTO), fluorine-doped tin oxide (FTO), aluminum-doped zinc oxide (AZO), gallium-doped zinc oxide (GZO), In₄Sn₃O₁₂ and zinc magnesium oxide (ZnMgO).

The first and second n-electrodes 140a and 140b and the first and second p-electrodes 150a and 150b may contact a conductive wire, a solder bump or the like, and may contain at least one of gold (Au), tungsten (W), platinum (Pt), silicon (Si), iridium (Ir), silver (Ag), copper (Cu), nickel (Ni), titanium (Ti), chromium (Cr), and alloys thereof.

Referring to FIGS. 1 and 2A, the connection electrode 145 may be extended along a lateral surface of the first structure 120a and the device isolation region ISO so as to connect the first p-electrode 150a of the first structure 120a and the second n-electrode 140b of the second structure 120b to each other. In addition, the connection electrode 145 may be formed to extend from the finger portion 152 of the first p-electrode 150a. The connection electrode 145 may be insulated from the first and second structures 120a and 120b by an insulating layer 180. As shown in FIG. 2A, a side of the first structure 120a on which the connection electrode 145 is formed may be mesa etched. However, according to an embodiment of the inventive concept, a side of the first structure 120a on which the connection electrode 145 is formed may not be mesa etched, but may be formed in a linear or inclined linear manner.

FIG. 3 is an equivalent circuit diagram of a semiconductor light emitting device according to an embodiment of the inventive concept.

With reference to FIG. 3, a first diode D1, e.g., a light emitting diode, may be connected in parallel with a second diode D2, e.g., a zener diode. The second diode D2 may be connected to the first diode D1 through opposing polarities. The first and second diodes D1 and D2 may be disposed in the light emitting diode region R1 and the zener diode region R2, respectively, with reference to FIGS. 1 to 2B, and may be configured of the first and second structures 120a and 120b, respectively.

When a normal forward voltage is applied to two terminals V1 and V2 of the first diode, a majority of current flows through a p-n junction of the first diode D1, such that a forward current for light emission may be formed. However, when a momentarily reversed high voltage, for example, an ESD voltage through a reverse electrostatic discharge (ESD) is applied, the second diode D2 may be turned on. Accordingly, since a majority of current through the ESD voltage may flow through the second diode D2 instead of the first diode D1, the first diode D1 may be prevented from being damaged thereby.

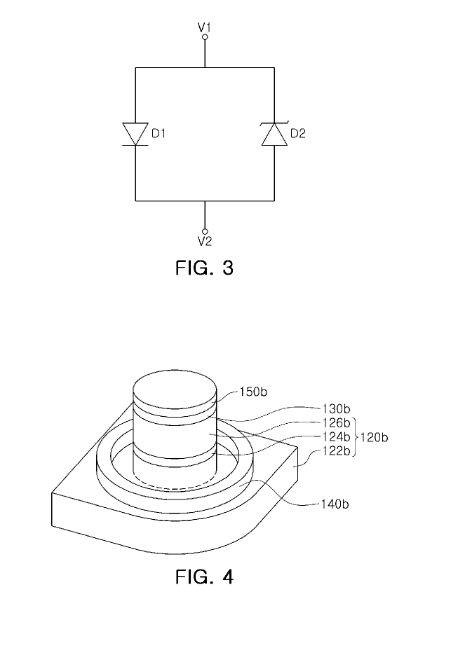

FIG. 4 is a schematic perspective view illustrating a zener diode region of a semiconductor light emitting device according to an embodiment of the inventive concept. FIG. 4 illustrates an exemplary embodiment of the present inventive concept in which a portion of constituent elements configuring the semiconductor light emitting device 100 of FIGS. 1 to 2B, for example, the substrate 101, is omitted.

With reference to FIG. 4, the zener diode region may include the second structure 120b, the second n-electrode 140b, and the second p-electrode 150b, to thereby configure a zener diode. The second structure 120b may have a mesa etched shape, and may have a cylindrical shape including a portion of the second n-type semiconductor layer 122b, the second active layer 124b and the second p-type semiconductor layer 126b on the second n-type semiconductor layer 122b.

The transparent electrode layer 130b and the second p-electrode 150b may be formed on the second p-type semiconductor layer 126b and may have a circular cross-sectional shape. The second n-electrode 140b may be formed to have a ring shape so as to encompass the second active layer 124b on the second n-type semiconductor layer 122b. The second n-electrode 140b may be spaced apart from the second active layer 124b by a predetermined distance so as to encompass a structure including a portion of the second n-type semiconductor layer 122b, the second active layer 124b and the second p-type semiconductor layer 126b.

As such, the second n-electrode 140b and the second p-electrode 150b may be disposed such that charges due to an ESD voltage may be efficiently dispersed to thus prevent the occurrence of a phenomenon in which charges are concentrated on a portion of the second n-electrode 140b to deteriorate a performance of a zener diode. According to simulation results, the zener diode according to the embodiment of FIG. 4 exhibited forward diode characteristics in which the maximum current density has been reduced from 72.9 A/cm² to about 44.7 A/cm² to 45.0 A/cm², as compared to a zener diode with a general structure having the same area as that of the zener diode according to the embodiment of FIG. 4 but not having a circular-shaped electrode. It can be appreciated through such characteristics that the zener diode according to an embodiment of the inventive concept may significantly reduce the occurrence of a current crowding phenomenon at the time of being operated, and it may also be expected that an ESD withstand voltage is able to be increased.

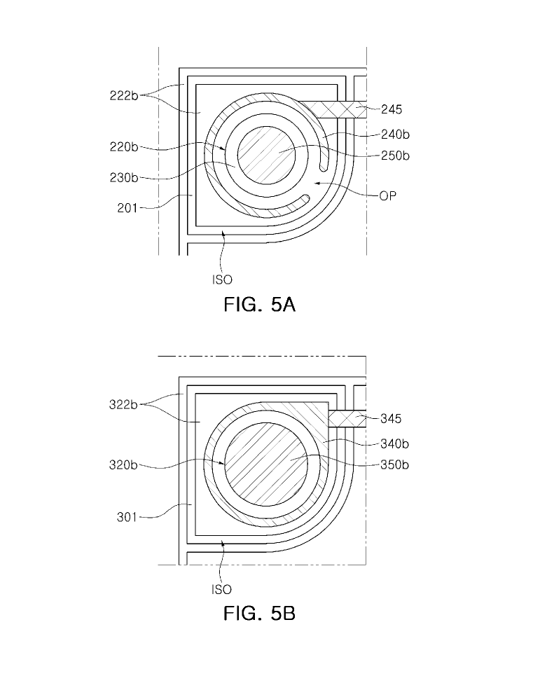

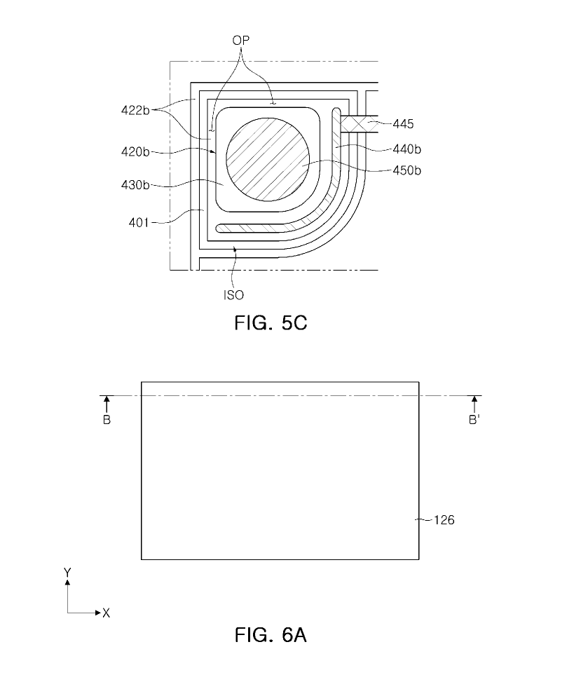

FIGS. 5A to 5C are schematic plan views illustrating zener diode regions of a semiconductor light emitting device according to an embodiment of the inventive concept.

With reference to FIG. 5A, a zener diode region may include a second structure 220b including a second n-type semiconductor layer 222b, a transparent electrode layer 230b, a second n-electrode 240b, and a second p-electrode 250b, and may be separated from regions adjacent thereto by a device isolation region ISO in which the second structure 220b is etched and to which a substrate 201 is exposed.

In an embodiment of the inventive concept, referring to FIG. 5A, the second n-electrode 240b may have an open curved shape having an open portion OP. Such a structure may be applicable, for example, when a distance between the second structure 220b and the first structure (not shown in FIG. 5A) is not relatively great. A ratio of the open portion OP may be selected to be within a range of about 70% or less of the entirety (100%) of the second n-electrode 240b. When the ratio of the open portion OP is higher than 70%, an effect in which the current crowding phenomenon may be significantly reduced according to the inventive concept may not be exhibited. The second n-electrode 240b may be connected to a connection electrode 245 at a portion thereof.

In addition, the second p-electrode 250b may have an area smaller than those of an upper surface of a mesa region of the second structure 220b and the transparent electrode layer 230b and may be formed on the transparent electrode layer 230b. For example, the second p-electrode 250b may be formed only on a portion of the transparent electrode layer 230b.

With reference to FIG. 5B, a zener diode region may include a second structure 320b including a second n-type semiconductor layer 322b, a second n-electrode 340b, and a second p-electrode 350b, and may be separated from regions adjacent thereto by a device isolation region ISO in which the second structure 320b is etched and to which a substrate 301 is exposed.

In the embodiment of FIG. 5B, the second n-electrode 340b may be formed in a manner in which a width thereof is widened in at least a portion thereof. As shown in FIG. 5B, the second n-electrode 340b may have a greater width in a region contacting a connection electrode 345. By such a structure, the connection to the connection electrode 345 may be further stabilized.

In addition, the second p-electrode 350b may have an area the same as or similar to those of the second structure 320b, an upper surface of a mesa region of the second structure 320b and a transparent electrode layer (not shown) and may be formed on the transparent electrode layer. Therefore, a lateral surface of the second p-electrode 350b may extend to (or be coplanar with, if the lateral surface is planar) a lateral surface of the mesa region of the second structure 320b and a lateral surface of the transparent electrode layer.

According to simulation results, in the case of a zener diode in which the second p-electrode 350b is formed to cover the entire upper surface of the mesa region of the second structure 320b, forward diode characteristics in which the maximum current density has been reduced by about 0.3 A/cm² were exhibited, as compared to the zener diode having the structure of the second p-electrode 250b shown in FIG. 5A, only formed in a portion of a region thereof. Therefore, it may be considered that when the second p-electrode 350b has a relatively wide area, a current dispersion may be relatively effective.

With reference to FIG. 5C, a zener diode region may include a second structure 420b including a second n-type semiconductor layer 422b, a transparent electrode layer 430b, a second n-electrode 440b, and a second p-electrode 450b, and may be separated from regions adjacent thereto by a device isolation region ISO in which the second structure 420b is etched and to which a substrate 401 is exposed. The second n-electrode 440b may be connected to a connection electrode 445 in a portion thereof.

In the embodiment of FIG. 5C, the second n-electrode 440b may have an open curved shape having an open portion OP. By employing such a structure therein, the size of the second structure 420b may be increased in a single area. In an embodiment of the inventive concept, referring to FIG. 5C, a ratio of the open portion OP may be selected to be within a range of, for example, 70% or less of the entirety (100%) of the second n-electrode 440b. When the ratio of the open portion OP is higher than 70%, an effect that the current crowding phenomenon may be significantly reduced according to the inventive concept may not be exhibited. As the evaluation result, it was measured that withstand voltage against a reverse ESD was within a range of 4.5 KV to 8.0 KV according to a ratio of the open portion OP.

In addition, the second structure 420b according to an embodiment of the inventive concept may have a corner-rounded quadrangular shape. For example, as shown in FIG. 5C, the second structure 420b may have a shape defined as including straight line and curved line regions.

The second p-electrode 450b according to the embodiment of FIG. 5C may be formed on the transparent electrode layer 430b so as to have a circular cross-sectional shape, but according to an embodiment of the inventive concept, the second p-electrode 450b may have a shape similar to that of the second structure 420b.

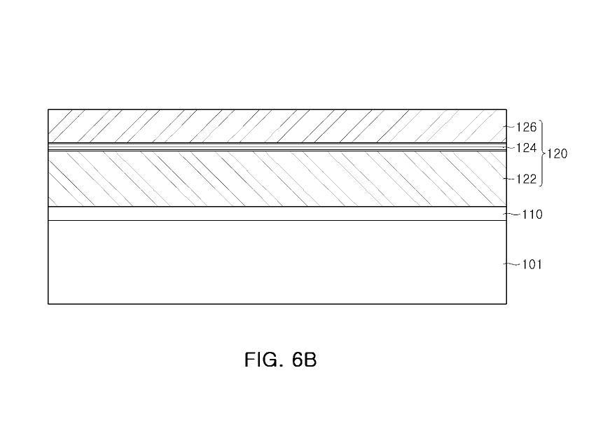

FIGS. 6A to 10B schematically illustrate main processes of a method of manufacturing a semiconductor light emitting device according to an embodiment of the inventive concept. In FIGS. 6A to 10B, the same reference numbers as FIGS. 1 to 2B refer to the same members, and thus descriptions of overlapped portions will be omitted.

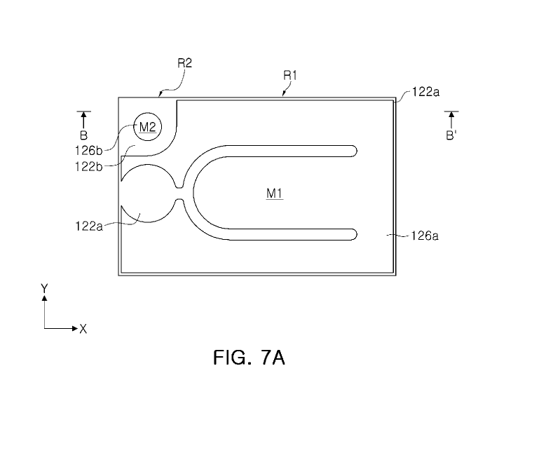

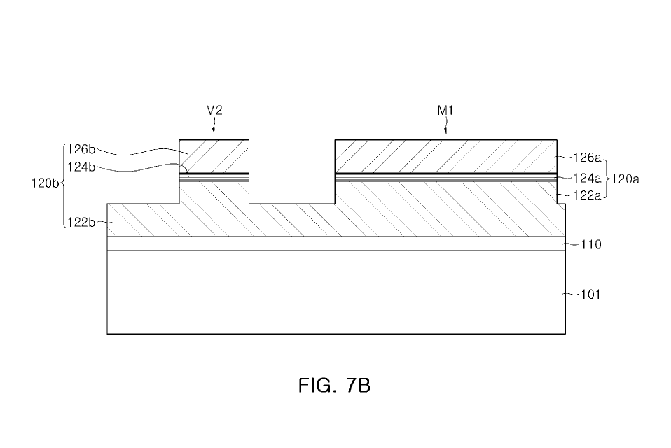

With reference to FIGS. 6A and 6B, FIG. 6A is a plan view of a region corresponding to the region of FIG. 1, and FIG. 6B is a cross-sectional view taken along line B-B′ of FIG. 6A. FIGS. 7A to FIG. 10B are illustrated in the same manner as above.

First, a buffer layer 110 may be formed on a substrate 101. However, according to an embodiment of the inventive concept, the buffer layer 110 may be omitted. As described above, the substrate 101 may be formed using a substrate formed of a material such as sapphire, silicon carbide (SiC), MgAl₂O₄, magnesium oxide (MgO), LiAlO₂, LiGaO₂, gallium nitride (GaN) or the like, and the buffer layer 110 may be formed of a material such as undoped GaN, undoped AlN, undoped InGaN or the like.

Subsequently, a stacked structure 120 may be formed to include an n-type semiconductor layer 122, an active layer 124 and a p-type semiconductor layer 126 sequentially grown on the buffer layer 110 using a process such as metal organic chemical vapor deposition (MOCVD), hydride vapor phase epitaxy (HVPE), molecular beam epitaxy (MBE), or the like. In the stacked structure 120, positions of the n-type semiconductor layer 122 and the p-type semiconductor layer 126 may be switched to each other, and the p-type semiconductor layer 126 may first be formed on the buffer layer 110.

With reference to FIGS. 7A and 7B, portions of the n-type semiconductor layer 122, the active layer 124, and the p-type semiconductor layer 126 may be etched to expose at least a portion of the n-type semiconductor layer 122. Thus, the first and second structures 120a and 120b may be formed in the light emitting diode region R1 and the zener diode region R2, respectively, and the first and second structures 120a and 120b may include non-etched regions, first and second mesa regions M1 and M2, respectively.

In the light emitting diode region R1, the first n-type semiconductor layer 122a may be exposed through an etching process in a region in which the first n-electrode 140a (see FIG. 1) is to be formed, and in the zener diode region R2, the second n-type semiconductor layer 122b may be exposed through the etching process in a region thereof including a region in which the second n-electrode 140b (see FIG. 1) is to be formed.

A mask layer may be formed in a region except for the region to which the first and second n-type semiconductor layers 122a and 122b are exposed through the etching process, and the first and second mesa regions M1 and M2 may then be formed through wet or dry etching. According to an embodiment of the inventive concept, the etching process may be performed such that the first and second n-type semiconductor layers 122a and 122b are not entirely etched, but only an upper surface thereof is partially exposed.

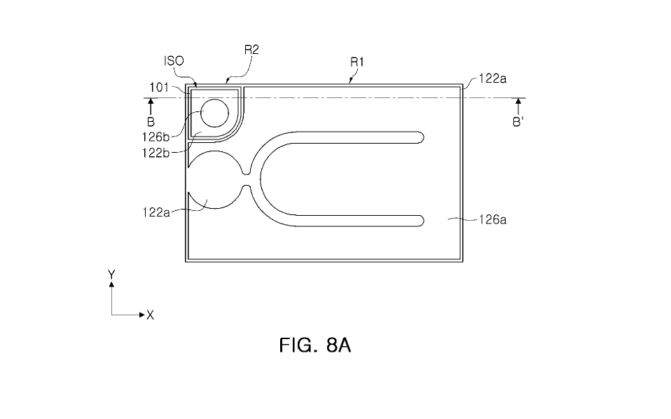

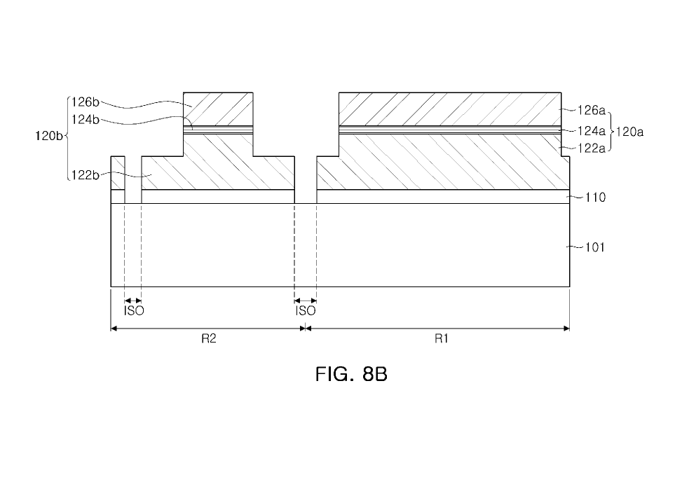

With reference to FIGS. 8A and 8B, in order to form the device isolation region ISO surrounding the zener diode region R2, the first and second n-type semiconductor layers 122a and 122b and the buffer layer 110 may be partially removed. According to an embodiment of the inventive concept, a portion of the substrate 101 may also be removed together.

The device isolation region ISO may have a band form so as to surround the second mesa region M2 therethrough, and the substrate 101 may be exposed in the device isolation region ISO. Accordingly, the zener diode region R2 may be electrically isolated from the light emitting diode region R1.

According to an embodiment of the inventive concept, the device isolation region ISO may be extended from sides of the zener diode region R2 which are not facing the light emitting diode region R1 to end portions of the semiconductor light emitting device. In addition, at this stage, the first and second n-type semiconductor layers 122a and 122b and the buffer layer 110 may be partially removed to expose the substrate 101 in edge regions of the semiconductor light emitting device. Alternatively, according to an embodiment of the inventive concept, the device isolation region ISO may also be formed to contact the first mesa region M1 in a region contacting the light emitting diode region R1. In this case, in the light emitting diode region R1 opposing the zener diode region R2, the first n-type semiconductor layer 122a may have a straight lateral surface without a curved portion therein.

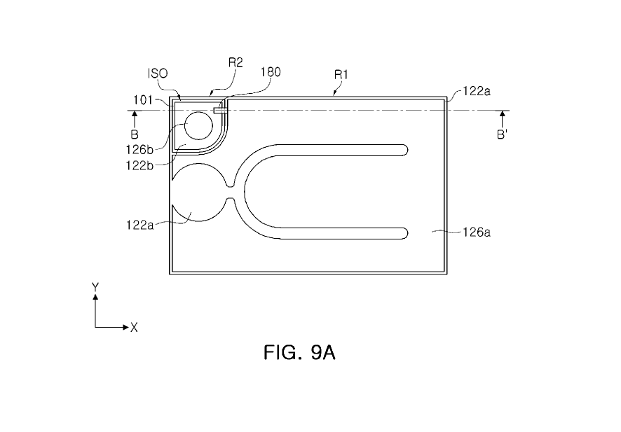

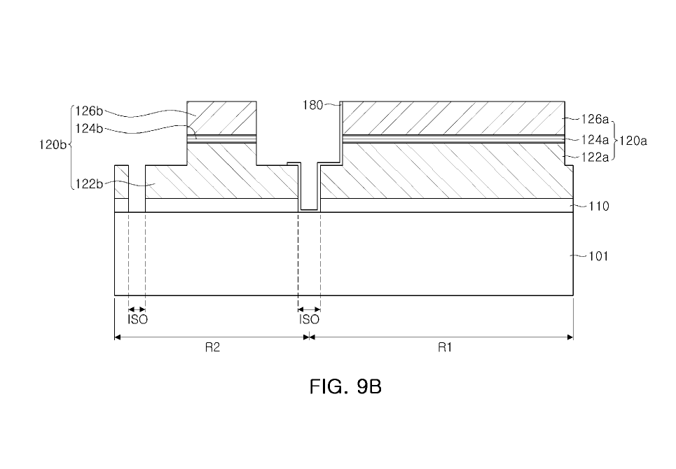

Referring to FIGS. 9A and 9B, an insulating layer 180 may be formed to cover portions of upper surfaces and lateral surfaces of the first structure 120a and the second structure 120b. The insulating layer 180 may be a layer for insulating the connection electrode 145 (see FIG. 2A) from the substrate 101 and the first and second structures 120a and 120b and may be formed in a region in which the connection electrode 145 is disposed. The insulating layer 180 may be formed of, for example, a light transmitting material such as a silicon oxide, a silicon nitride or the like.

According to an embodiment of the inventive concept, the insulating layer 180 may also be formed to cover portions of upper surfaces and lateral surfaces of the first and second structures 120a and 120b in other regions. For example, as shown in FIG. 9B, in a region between the light emitting diode region R1 and the zener diode region R2, the insulating layer 180 may be formed to cover the entire lateral surfaces of the first structure 120a and an upper surface of the first n-type semiconductor layer 122a and to cover a portion of lateral surfaces of the second structure 120b and a portion of an upper surface of the second n-type semiconductor layer 122b. In this case, the insulating layer 180 may serve as a passivation layer protecting the first and second structures 120a and 120b and/or a current blocking layer below the first p-electrode 150a (see FIG. 1). For example, the current blocking layer may be formed to have a predetermined size in a region corresponding to the pad portion 151 (see FIG. 1) of the first p-electrode 150a.

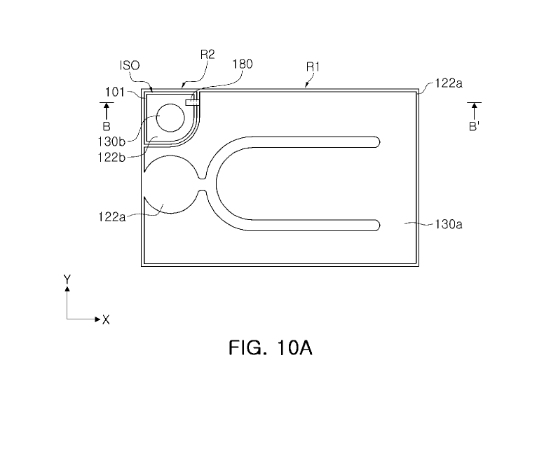

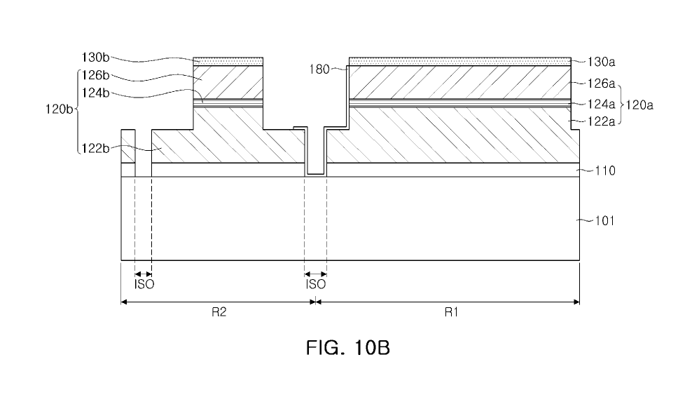

With reference to FIGS. 10A and 10B, transparent electrode layers 130a and 130b may be formed on the first and second p-type semiconductor layers 126a and 126b, respectively.

The transparent electrode layer 130a and 130b may be formed of a material such as indium tin oxide (ITO), copper indium oxide (CIO), zinc oxide (ZnO), or the like. According to an embodiment of the inventive concept, the transparent electrode layers 130a and 130b may not be formed in at least a portion of a region in which the first p-electrode 150a (see FIG. 1) is to be formed, on the first p-type semiconductor layer 126a.

Then, with reference to FIGS. 1 and 2A, the first and second n-electrodes 140a and 140b, the first and second p-electrodes 150a and 150b, and the connection electrode 145 may be formed on the first and second structures 120a and 120b. The first and second n-electrodes 140a and 140b, the first and second p-electrodes 150a and 150b, and the connection electrode 145 may be formed simultaneously or may also be sequentially formed.

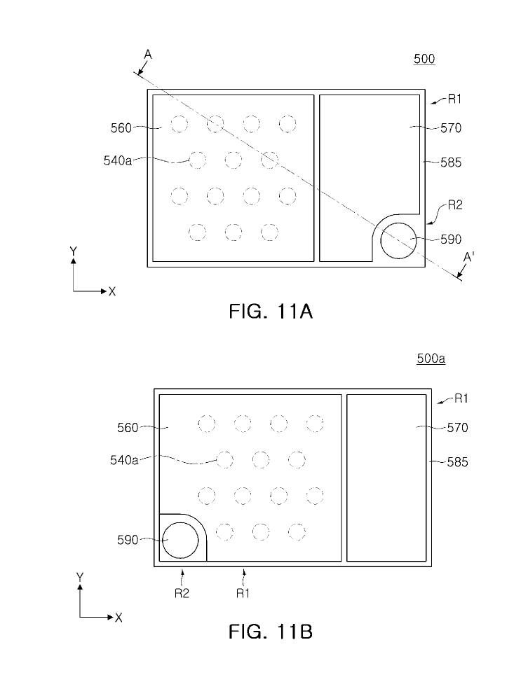

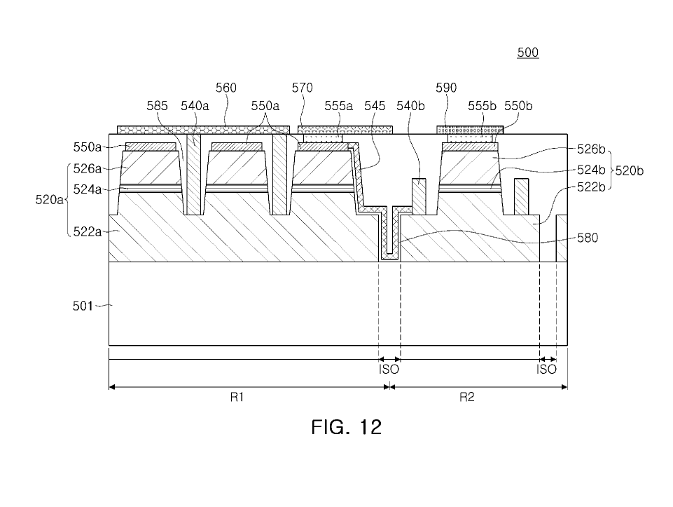

FIGS. 11A and 11B are schematic plan views of a semiconductor light emitting device according to an embodiment of the inventive concept. FIG. 12 is a schematic cross-sectional view of a semiconductor light emitting device taken along line A-A′ of FIG. 11A.

With reference to FIGS. 11A to 12, a semiconductor light emitting device 500 or 500a may include a light emitting diode region R1 including a first structure 520a formed therein and a zener diode region R2 including a second structure 520b formed therein. The zener diode region R2 may be electrically isolated from the light emitting diode region R1 through a device isolation region ISO. As shown in FIGS. 11A and 11B, the zener diode region R2 may be formed on different locations on a substrate 501 according to an embodiment of the inventive concept.

Referring to FIG. 12, the first and second structures 520a and 520b, including multiple first structures 520a, may include first and second n-type semiconductor layers 522a and 522b, first and second active layers 524a and 524b, and first and second p-type semiconductor layers 526a and 526b, respectively. In addition, the semiconductor light emitting device 500 or 500a may include a first p-electrode 550a formed on the first structure 520a, a first n-electrode 540a formed between the first structures 520a, a second n-electrode 540b formed on the second n-type semiconductor layer 522b, and a second p-electrode 550b formed on the second structure 520b, as an electrode structure. The semiconductor light emitting device 500 or 500a may further include first and second contact electrodes 555a and 555b and first to third pad electrodes 560, 570 and 590.

In an embodiment of the inventive concept, the first n-electrode 540a may be provided in the form of a conductive via penetrating through the first p-type semiconductor layer 526a and the first active layer 524a to be connected to the first n-type semiconductor layer 522a. The first n-electrode 540a may be surrounded by an interlayer insulating layer 585 so as to be electrically insulated from the first active layer 524a and the first p-type semiconductor layer 526a. The first n-electrode 540a may be disposed in a region in which the first structure 520a is etched, and an inclination angle of a lateral surface of the first structure 520a may be changed according to an embodiment of the inventive concept. The first n-electrode 540a may be appropriately controlled in terms of the number thereof, a shape, a pitch, a contact area with the first n-type semiconductor layer 522a, or the like, so as to reduce contact resistance. In addition, as shown in FIG. 11A, the first n-electrodes 540a may be arrayed while forming rows and columns, thereby providing improved current flow.

The first p-electrode 550a may be connected to the first p-type semiconductor layer 526a on the first p-type semiconductor layer 526a and may be connected to the second n-electrode 540b of the zener diode region R2 through the connection electrode 545. The connection electrode 545 may be insulated from the first and second structures 520a and 520b by an insulating layer 580.

The first to third pad electrodes 560, 570 and 590 may function as external terminals of the semiconductor light emitting device 500 or 500a. The first pad electrode 560 may be connected to the first n-electrode 540a, and the second pad electrode 570 may be connected to the first p-electrode 550a through the first contact electrode 555a to then be electrically connected to the second n-electrode 540b through the connection electrode 545.

The third pad electrode 590 may be connected to the second p-electrode 550b through the second contact electrode 555b.

As illustrated in FIGS. 11A and 11B, the layout of the first to third pad electrodes 560, 570 and 590 may be changed depending on a relative layout of the first and second structures 520a and 520b.

The substrate 501 may be a transparent substrate. For example, when the semiconductor light emitting device 500 is mounted in an external apparatus in order to be applied to a package, a light source module, or the like, a so-called flip-chip type semiconductor light emitting device in which the substrate 501 is directed upwardly may be used. In this case, in the external apparatus, the first pad 560 and the third pad 590 may be electrically connected to each other, and thus, the first n-electrode 540a and the second p-electrode 550b may be electrically connected to each other, such that the second structure 520b may function as a zener diode.

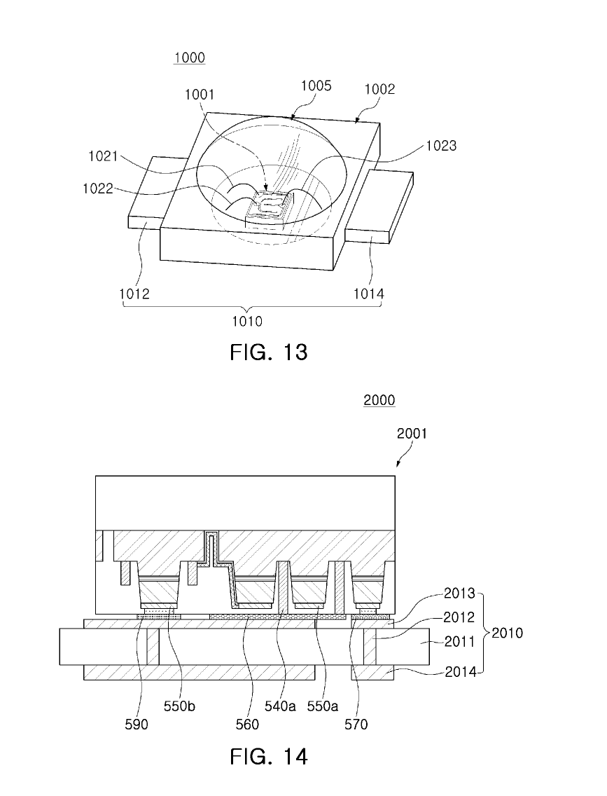

FIGS. 13 and 14 are respectively a perspective view and a cross-sectional view illustrating an example in which a semiconductor light emitting device according to an embodiment of the inventive concept is applied to a package.

With reference to FIG. 13, a semiconductor light emitting device package 1000 may include a semiconductor light emitting device 1001, which is the same as or similar to the semiconductor light emitting device 100 in FIG. 1, a package body 1002, and a pair of lead frames 1010. The semiconductor light emitting device 1001 may be mounted on the lead frame 1010 to be electrically connected to the lead frame 1010 through first to third wires 1021, 1022 and 1023.

The lead frame 1010 may include first and second lead frames 1012 and 1014. With reference to FIG. 13 and FIG. 1, first and second wires 1021 and 1022 may respectively connect a second p-electrode 150b and a first n-electrode 140a of the semiconductor light emitting device 1001 to the first lead frame 1012, and the third wire 1023 may connect a first p-electrode 150a of the semiconductor light emitting device 1001 to the second lead frame 1014.

According to an embodiment of the inventive concept, the semiconductor light emitting device 1001 may also be mounted on other regions instead of the lead frame 1010, for example, on the package body 1002. In addition, the package body 1002 may have a cup shape to improve light reflection efficiency. Such a reflective cup may be provided with an encapsulating portion 1005 formed of a light transmitting material and encapsulating the semiconductor light emitting device 1001, the first to third wires 1021, 1022 and 1023, and the like. In an embodiment of the inventive concept, although the semiconductor light emitting device package 1000 is illustrated as including the semiconductor light emitting device 100 shown in FIGS. 1 to 2B, the semiconductor light emitting device package 1000 may include the semiconductor light emitting device 500 or 500a shown in FIGS. 11A to FIG. 12 according to an embodiment of the inventive concept.

Referring to FIG. 14, a semiconductor light emitting device package 2000 may include a semiconductor light emitting device 2001, which is the same as or similar to the semiconductor light emitting device 500 in FIG. 12, and a mounting substrate 2010. Although not shown in the drawing, a wavelength converting portion may be further formed on a surface and a side of the semiconductor light emitting device 2001.

With reference to FIG. 14 and FIG. 11b, the semiconductor light emitting device 2001 may be mounted on the mounting substrate 2010 to be electrically connected thereto through the first to third pad electrodes 560, 570 and 590.

The first and third pad electrodes 560 and 590 may respectively connect the first n-electrode 540a and the second p-electrode 550b of the semiconductor light emitting device 2001 to a portion of an upper surface electrode 2013 of the mounting substrate 2010. The third pad electrode 570 may connect the first p-electrode 550a of the semiconductor light emitting device 2001 to another region of the upper surface electrode 2013 of the mounting substrate 2010.

The mounting substrate 2010 may include a substrate body 2011, the upper surface electrode 2013 and a lower surface electrode 2014. In addition, the mounting substrate 2010 may include a through electrode 2012 connecting the upper surface electrode 2013 to the lower surface electrode 2014. The mounting substrate 2010 may be provided as a substrate such as a printed circuit board (PCB), a metal-core printed circuit board (MCPCB), a metal printed circuit board (MPCB), a flexible printed circuit board (FPCB), or the like. The structure of the mounting substrate 2010 may be variously applied.

In an embodiment of the inventive concept, although the semiconductor light emitting device package 2000 may include the semiconductor light emitting device 500 or 500a as shown in FIG. 11A to FIG. 12, the semiconductor light emitting device package 2000 may also include the semiconductor light emitting device 100 shown in FIG. 1 to FIG. 2A according to an embodiment of the inventive concept.

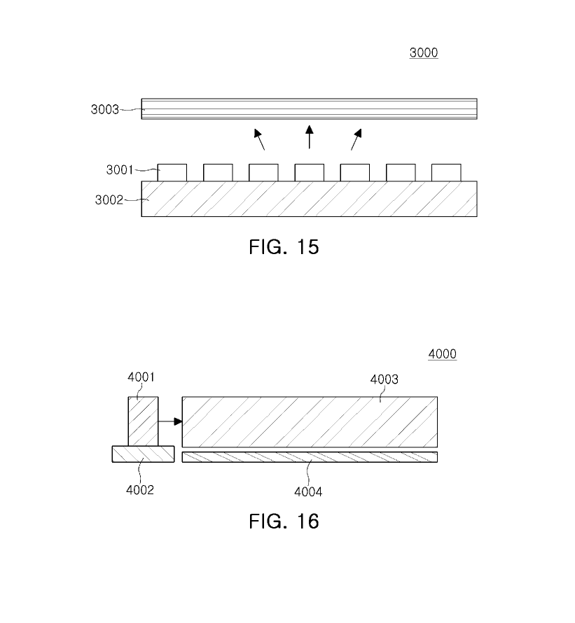

FIGS. 15 and 16 are cross-sectional views illustrating examples in which a semiconductor light emitting device according to an embodiment of the inventive concept is applied to a backlight unit.

With reference to FIG. 15, a back light unit 3000 may include a light source 3001 mounted on a substrate 3002 and at least one optical sheet 3003 disposed thereabove. As the light source 3001, a light emitting device package having the afore-described structure with reference to FIGS. 13 and 14 or a structure similar thereto may be used. In addition, the light source 3001 may be used by directly mounting a semiconductor light emitting device on the substrate 3002 (in a so-called chip on board (COB) mounting manner).

In the back light unit 3000 of FIG. 15, the light source 3001 emits light upwardly in a direction in which a liquid crystal display device is disposed, while in a back light unit 4000 of another example illustrated in FIG. 16, a light source 4001 mounted on a substrate 4002 emits light in a lateral direction such that the emitted light may be incident onto a light guiding panel 4003 to be converted into a form of surface light source type light. As the light source 4001, a light emitting device package having the afore-described structure with reference to FIGS. 13 and 14 or a structure similar thereto may be used. Light, having passed through the light guiding panel 4003, may be discharged in an upward direction, and a reflective layer 4004 may be disposed below the light guiding panel 4003 to improve light extraction efficiency.

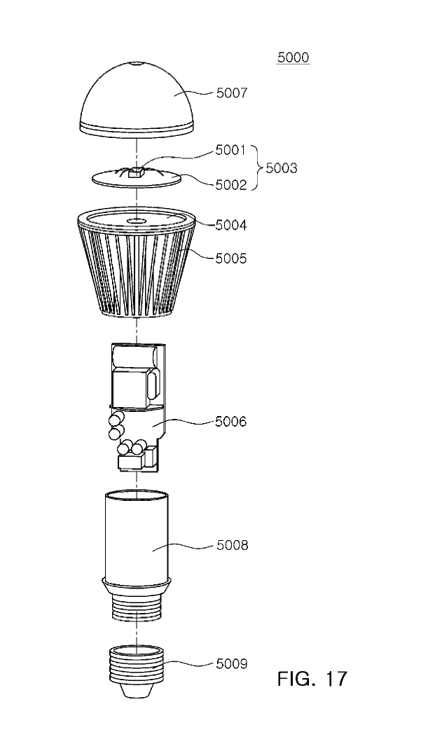

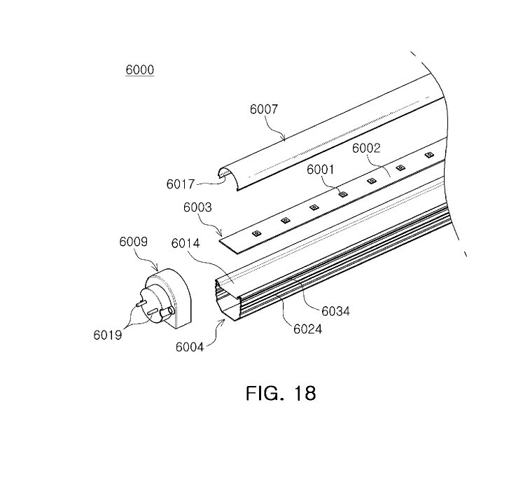

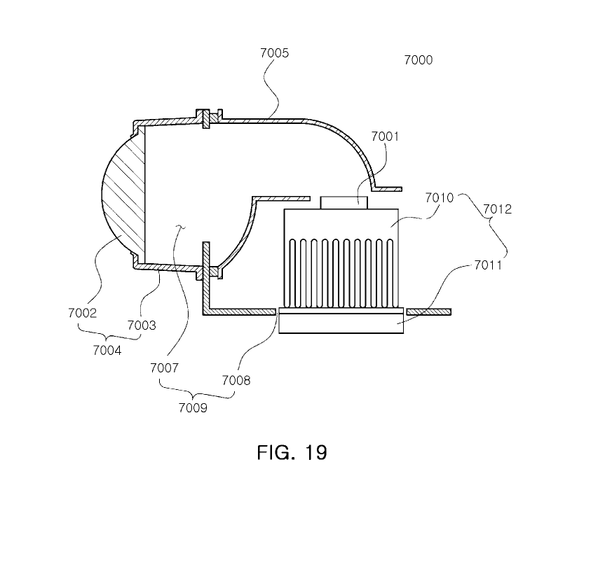

FIGS. 17 and 18 are exploded perspective views illustrating examples in which a semiconductor light emitting device according to an embodiment of the inventive concept is applied to an illumination device.

With reference to FIG. 17, an illumination apparatus 5000 may be a bulb-type lamp and may include a light emitting module 5003, a driving unit 5006, and an external connection unit 5009. In addition, the illumination apparatus 5000 may further include an outer structure such as an external housing 5005, an internal housing 5008, and a cover unit 5007.

The light emitting module 5003 may include the semiconductor light emitting device 5001 having the same structure as or a structure similar to the semiconductor light emitting device 100 of FIGS. 1 to 2B or the semiconductor light emitting device 500 or 500a of FIGS. 11A to 12, and a circuit board 5002 having the semiconductor light emitting device 5001 mounted thereon. Although an embodiment of the inventive concept describes the case in which a single semiconductor light emitting device 5001 is mounted on the circuit board 5002, a plurality of semiconductor light emitting devices may be mounted thereon as needed. In addition, instead of directly mounting the semiconductor light emitting device 5001 on the circuit board 5002, the semiconductor light emitting device 5001 may be manufactured as a package type light emitting device and then mounted.

The external housing 5005 may serve as a heat radiating portion, and may include a heat radiating plate 5004 directly contacting the light emitting module 5003 to improve a heat radiation effect and heat radiating fins 5005 disposed to encompass a peripheral surface of the illumination apparatus 5000. The cover unit 5007 may be mounted on the light emitting module 5003 and may have a convex lens shape. The driving unit 5006 may be installed in the internal housing 5008 to be connected to the external connection unit 5009 having a structure such as a socket structure so as to receive power from an external power supply. In addition, the driving unit 5006 may convert the received power into a current source suitable for driving a light source, for example, the semiconductor light emitting device 5001 of the light emitting module 5003 to then be supplied. For example, the driving unit 5006 may be configured of an AC-DC converter, a rectifying circuit component, or the like.

In addition, although not shown in FIG. 17, the illumination apparatus 5000 may further include a communications module.

With reference to FIG. 18, an illumination apparatus 6000 may be, for example, a bar-type lamp, and may include a light emitting module 6003, a body part 6004, a cover part 6007, and a terminal part 6009.

The light emitting module 6003 may include a substrate 6002 and a plurality of semiconductor light emitting devices 6001 installed on the substrate 6002. The semiconductor light emitting device 6001 may have a structure the same as or similar to the semiconductor light emitting device 100 of FIGS. 1 to 2B or the semiconductor light emitting device 500 or 500a of FIGS. 11A to 12.

The body part 6004 may have a recess 6014 in which the light emitting module 6003 is fixedly mounted on one surface thereof, and heat generated in the light emitting module 6003 may be discharged to the outside. Therefore, the body part 6004 may include a heat sink, a support structure, and may include a plurality of radiating fins 6024 protruding from both side surfaces thereof so as to radiate heat.

The cover part 6007 may be fastened to a holding groove 6034 of the body part 6004, and may have a semicircular curved surface so as to irradiate light externally in a uniform manner. On a bottom surface of the cover part 6007, a protrusion 6017 may be formed in a length direction thereof so as to be engaged with the holding groove 6034 of the body part 6004.

The terminal part 6009 may be provided at at-least one, open portion of both end portions of the body part 6004 in the length direction thereof, to supply power to the light emitting module 6003, and may include an electrode pin 6019 protruding outwardly thereof.

FIG. 19 illustrates an example in which a semiconductor light emitting device according to an embodiment of the inventive concept is applied to a vehicle headlight.

With reference to FIG. 19, a headlight 7000 for vehicle lighting or the like may include alight source 7001, a reflective unit 7005 and a lens cover unit 7004, and the lens cover unit 7004 may include a hollow guide 7003 and a lens 7002. The light source 7001 may include at least one among the semiconductor light emitting device packages of FIGS. 13 and 14. In addition, the headlight 7000 may further include a heat radiating unit 7012 discharging heat generated in the light source 7001 to the outside. The heat radiating unit 7012 may include a heat sink 7010 and a cooling fan 7011 to perform effective heat radiation. In addition, the headlight 7000 may further have a housing 7009 fixing and supporting the heat radiating unit 7012 and the reflective unit 7005, and the housing 7009 may include a body 7007 and a central hole 7008 for allowing the heat radiating unit 7012 to be coupled to one surface thereof. Further, the housing 7009 may include a front hole in the other surface integrally connected to the one surface to then be bent in a direction orthogonal thereto. The reflective unit 7005 may be fixed to the housing 7009 such that light generated in the light source 7001 may be reflected therefrom to be emitted to the outside through the front hole.

As set forth above, according to embodiments of the inventive concept, a semiconductor light emitting device having an improved withstand voltage against reverse ESD by forming one electrode of a zener diode to encompass an active layer, and a semiconductor light emitting apparatus including the same may be provided. In addition, as a zener diode has the same structure as that of a light emitting diode and is disposed along therewith in a single device, a semiconductor light emitting device having improved light emission efficiency and a semiconductor light emitting apparatus including the same may be provided.

While the inventive concept has been shown and described in connection with embodiments, it will be apparent to those skilled in the art that modifications and variations could be made without departing from the spirit and scope of the present inventive concept as defined by the appended claims.

1. A semiconductor light emitting device, comprising:
a substrate;
a first structure disposed on the substrate and including a first n-type semiconductor layer, a first active layer, and a first p-type semiconductor layer;
a second structure disposed to be spaced apart from the first structure on the substrate and including a second n-type semiconductor layer, a second active layer and a second p-type semiconductor layer; and
a first n-electrode and a first p-electrode connected to the first n-type semiconductor layer and the first p-type semiconductor layer, respectively; and
a second n-electrode and a second p-electrode connected to the second n-type semiconductor layer and the second p-type semiconductor layer, respectively,
wherein the second n-electrode is spaced apart from the second active layer so as to encompass the second active layer.

2. The semiconductor light emitting device of claim 1, wherein the semiconductor light emitting device includes a light emitting diode region in which the first structure is disposed and a zener diode region in which the second structure is disposed.

3. The semiconductor light emitting device of claim 1, wherein the second n-electrode is spaced apart from the second active layer at a uniform interval so as to encompass the second active layer.

4. The semiconductor light emitting device of claim 1, wherein the second active layer has a circular cross-sectional shape on a plane parallel to an upper surface of the substrate.

5. The semiconductor light emitting device of claim 4, wherein the second n-electrode has a ring shape so as to encompass the second active layer.

6. The semiconductor light emitting device of claim 1, wherein the second n-electrode has an open curved shape so as to encompass the second active layer.

7. The semiconductor light emitting device of claim 1, wherein the second structure includes a mesa region in a central portion thereof and an etched region including etched portion of the second n-type semiconductor layer, the second active layer and the second p-type semiconductor layer in the vicinity of the mesa region.

8. The semiconductor light emitting device of claim 7, wherein the mesa region has a cylindrical shape.

9. (canceled)

10. (canceled)

11. The semiconductor light emitting device of claim 7, wherein the second p-electrode is disposed on an upper surface of the mesa region, and the second n-electrode is disposed on the second n-type semiconductor layer in an upper part of the etched region to encompass the second active layer.

12. The semiconductor light emitting device of claim 1, wherein the first n-electrode is electrically connected to the second p-electrode, and the first p-electrode is electrically connected to the second n-electrode.

13. The semiconductor light emitting device of claim 12, further comprising a connection electrode connecting the first p-electrode to the second n-electrode.

14. (canceled)

15. The semiconductor light emitting device of claim 13, wherein the first p-electrode includes a pad portion and at least one finger portion extending from the pad portion, and the connection electrode extends from the finger portion.

16. The semiconductor light emitting device of claim 1, wherein the first n-type semiconductor layer, the first active layer and the first p-type semiconductor layer, and the second n-type semiconductor layer, the second active layer and the second p-type semiconductor layer each include the same material, and have substantially the same maximum thickness.

17. The semiconductor light emitting device of claim 1, wherein the second structure is located in a corner region of the substrate.

18. (canceled)

19. A semiconductor light emitting device, comprising:
a substrate;
a light emitting structure and a zener structure spaced apart from each other on the substrate and respectively including a plurality of first semiconductor layers and a plurality of second semiconductor layers; and
a zener electrode unit including a first electrode and a second electrode on the zener structure,
wherein the zener structure includes a mesa region including at least a portion of the plurality of first semiconductor layers, and the first electrode is spaced apart from the mesa region to encompass the mesa region.

20. The semiconductor light emitting device of claim 19, wherein the mesa region has a cylindrical shape and the first electrode has a ring shape to encompass the mesa region.

21. A semiconductor light emitting apparatus, comprising:
a package body having a first electrode structure and a second electrode structure; and
the semiconductor light emitting device of claim 1, located in the package body.

22. The semiconductor light emitting apparatus of claim 21, wherein the first electrode structure is electrically connected to the first n-electrode and the second p-electrode, and the second electrode structure is electrically connected to the first p-electrode and the second n-electrode.

23. The semiconductor light emitting apparatus of claim 21, wherein the first electrode structure includes conductive wires connected to the first n-electrode and the second p-electrode, and the second electrode structure includes a conducive wire connected to the first p-electrode.

24. (canceled)

25. (canceled)

26. A semiconductor light emitting device, comprising:
a substrate;
a first structure disposed on the substrate and including a first first-conductive-type semiconductor layer, a first active layer, and a first second-conductive-type semiconductor layer;
a second structure disposed to be spaced apart from the first structure on the substrate and including a second first-conductive-type semiconductor layer, a second active layer and a second second-conductive-type semiconductor layer; and
a first first-conductive-type electrode and a first second-conductive-type electrode connected to the first first-conductive-type semiconductor layer and the first second-conductive-type semiconductor layer, respectively; and
a second first-conductive-type electrode and a second second-conductive-type electrode connected to the second first-conductive-type semiconductor layer and the second second-conductive-type semiconductor layer, respectively,
wherein the second first-conductive-type electrode is spaced apart from the second active layer so as to encompass the second active layer.
